(19) United States
(12) Patent Application Publication
(10) Pub. No.: US 2014/0353747 A1
(43) Pub. Date: Dec. 4, 2014

(54) TRENCH GATE MOSFET AND METHOD OF FORMING THE SAME

(71) Applicant: BEYOND INNOVATION TECHNOLOGY CO., LTD., TAIPEI CITY (TW)

(72) Inventor: Chien-Hsing Cheng, Taipei City (TW)

(73) Assignee: BEYOND INNOVATION TECHNOLOGY CO., LTD., TAIPEI CITY (TW)

(21) Appl. No.: 14/190,107

(22) Filed: Feb. 26, 2014

(30) Foreign Application Priority Data
May 31, 2013 (TW) 102119353

(51) Int. Cl. H01L 29/78; H01L 29/66

(52) U.S. Cl. CPC H01L 29/7827; H01L 29/66666
USPC 257/334; 438/270

(57) ABSTRACT

A trench gate MOSFET is provided. An N-type epitaxial layer is disposed on an N-type substrate. An N-type source region is disposed in the N-type epitaxial layer. The N-type epitaxial layer has at least one trench therein. An insulating layer serving as a gate insulating layer is disposed in the trench. A conductive layer serving as a gate fills up the trench. Two isolation structures are disposed in the N-type source region beside the trench and contact the trench. Two conductive plugs are disposed in the N-type epitaxial layer beside the trench and penetrate through the N-type source region. A dielectric layer is disposed on the N-type epitaxial layer. A metal layer is disposed on the dielectric layer and electrically connected to the N-type source region.

### CROSS-REFERENCE TO RELATED APPLICATION

This application claims the priority benefit of Taiwan application serial no. 102119353, filed on May 31, 2013. The entirety of the above-mentioned patent application is hereby incorporated by reference herein and made a part of this specification.

### BACKGROUND OF THE INVENTION

1. Field of the Invention

The invention relates to a semiconductor device and a method of forming the same, and more particularly, to a trench gate metal-oxide-semiconductor field effect transistor (MOSFET) and a method of forming the same.

2. Description of Related Art

Trench gate MOSFET has been widely applied in power switch devices, such as power supplies, rectifiers, low-voltage motor controllers, or so forth. In general, the trench gate MOSFET is often resorted to a design of vertical structure to enhance the device density. For each power MOSFET, each drain region is formed on the back-side of a chip, and each source region and each gate are formed on the front-side of the chip. The drain regions of the transistors are connected in parallel so as to endure a considerable large current.

A working loss of the trench gate MOSFET may be divided into a switching loss and a conducting loss, wherein the switching loss caused by the input capacitance Cᵢₛₛ is going up as the operation frequency is increased. The input capacitance Cᵢₛₛ includes a gate-to-source capacitance C_{gs} and a gate-to-drain capacitance C_{gd}. Therefore, how to reduce the input capacitance Cᵢₛₛ by effectively reducing the gate-to-source capacitance C_{gs} has become the major concern in industries.

Furthermore, the channel “on” resistance (Ron) and the breakdown voltage (BV) of the trench gate MOSFET usually maintain a power relationship of 2.4-2.5, that is, Ron ∝(BV)^{2.4-2.5.} In other words, as the rated voltage is higher, the chip size is greater, and therefore the Ron is also increased. Accordingly, achieving higher withstand voltage and lower Ron while maintaining the same or smaller chip size has become the greatest challenge in the design of the trench gate MOSFET.

### SUMMARY OF THE INVENTION

The invention provides a trench gate MOSFET and a method of forming the same. The method can form a trench gate MOSFET having higher withstand voltage and lower Ron while maintaining the same or smaller chip size.

The invention provides a method of forming a trench gate MOSFET. An epitaxial layer of a first conductivity type is formed on a substrate of the first conductivity type. A source region of the first conductivity type is foil led in the epitaxial layer. At least two first trenches are formed in the source region. A plurality of first insulating layers are completely filled in the first trenches to form a plurality of isolation structures, respectively. A second trench is formed in the epitaxial layer. The isolation structures are located beside the second trench and in contact with the second trench. A second insulating layer is formed in the second trench. A first conductive layer is filled in the second trench. Two third trenches are formed in the epitaxial layer beside the second trench. A plurality of second conductive layers are filled in the third trenches, respectively.

In an embodiment of the invention, the method further includes, before forming the first trenches: forming a first doped region of a second conductivity type in the epitaxial layer below the source region, and forming a second doped region of the first conductivity type in the epitaxial layer below the first doped region.

In an embodiment of the invention, a method of forming each of the source region, the first doped region and the second doped region includes performing a blanket implant process.

In an embodiment of the invention, a doping concentration of the second doped region is higher than a doping concentration of the epitaxial layer.

In an embodiment of the invention, the method further includes, after forming the first trenches and before completely filling the first insulating layers in the first trenches respectively: forming at least one third doped region of the second conductivity type in the epitaxial layer below each of the first trenches. The at least one third doped region is located below the second doped region.

In an embodiment of the invention, the third doped region is separated from the second trench.

In an embodiment of the invention, a portion of the third doped region is in contact with the second trench.

In an embodiment of the invention, the method further includes, after forming the third trenches in the epitaxial layer beside the second trench and before filling the second conductive layer in the third trenches, forming at least one fourth doped region of the second conductivity type in the epitaxial layer below each of the third trenches. The at least one fourth doped region is located below the second doped region.

In an embodiment of the invention, a doping concentration of the epitaxial layer located below the second doped region is equal to a sum of doping concentrations of the at least one third doped region and the at least one fourth doped region.

In an embodiment of the invention, the method further includes, after forming the third trenches and before filling the second conductive layer in the third trenches respectively, forming the third doped region of the second conductivity type in the first doped region below each of the third trenches.

In an embodiment of the invention, a method of forming the first insulating layer includes performing a local oxidation of silicon (LOCOS), a thermal oxidation process, or a chemical vapor deposition (CVD) process.

In an embodiment of the invention, the first conductivity type is N-type and the second conductivity type is P-type, or the first conductivity type is P-type and the second conductivity type is N-type.

The invention provides a trench gate MOSFET including a substrate of a first conductivity type, an epitaxial layer of the first conductivity type, a source region of the first conductivity type, an insulating layer, a conductive layer, two isolation structures and two conductive plugs. The epitaxial layer is disposed on the substrate, which the epitaxial layer has at least one trench. The source region is disposed in the epitaxial layer. The insulating layer is disposed in the trench. The conductive layer completely fills the trench. The two isolation structures are disposed in source region beside the trench and in contact with the trench. The two conductive plugs are disposed in the epitaxial layer beside the trench and penetrate through the source region.

In an embodiment of the invention, the trench gate MOSFET further includes a first doped region of a second conductivity type disposed in the epitaxial layer below the source region, and a second doped region of the first conductivity type disposed in the epitaxial layer below the first doped region.

In an embodiment of the invention, a doping concentration of the second doped region is higher than a doping concentration of the epitaxial layer.

In an embodiment of the invention, the trench gate MOSFET further includes at least two third doped regions of the second conductivity type disposed in the epitaxial layer below the second doped region. The third doped regions correspond to the isolation structures, respectively.

In an embodiment of the invention, the third doped regions are separated from the trench.

In an embodiment of the invention, a portion of the third doped regions is in contact with the trench.

In an embodiment of the invention, a width of each of the third trenches is substantially equal to or greater than a width of each of the isolation structures.

In an embodiment of the invention, the trench gate MOSFET further includes at least two fourth doped regions of the second conductivity type disposed in the epitaxial layer below the second doped region. The fourth doped regions correspond to the conductive plugs, respectively.

In an embodiment of the invention, a doping concentration of the epitaxial layer below the second doped region is equal to a sum of doping concentrations of the at least two third doped regions and the at least two fourth doped regions.

In an embodiment of the invention, the trench gate MOSFET further includes two third doped regions of the second conductivity type disposed in the first doped region below the conductive plugs, respectively.

In an embodiment of the invention, a material of the conductive layer includes doped poly-silicon. A material of the conductive plugs includes Ti, TiN, W, Al, or a combination thereof. A material of the isolation structures includes silicon oxide.

In an embodiment of the invention, the trench gate MOSFET further includes a dielectric layer disposed on the epitaxial layer, and a metal layer disposed on the dielectric layer and electrically connected to the source region.

In an embodiment of the invention, the first conductivity type is N-type and the second conductivity type is P-type, or the first conductivity type is P-type and the second conductivity type is N-type.

Based on the above, in the trench gate MOSFET of the invention, by disposing the isolation structures in the epitaxial layer adjoined to the gate, the gate-to-source capacitance C_{gs} is effectively reduced, thereby reducing the input capacitance Cᵢₛₛ. Furthermore, a super junction structure is formed in the epitaxial layer so as to make the device capable of having characteristics of high withstand voltage and low impedance. Therefore, the structure of the invention can obtain a lower Ron and a lower switching loss, thereby significantly improving the competitive advantage of the product.

In order to make the aforementioned features and advantages of the invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1H are schematic cross-sectional views of a method of forming a trench gate MOSFET according to an embodiment of the invention.

FIG. 2 is a schematic cross-sectional view of a trench gate MOSFET according to another embodiment of the invention.

### DESCRIPTION OF THE EMBODIMENTS

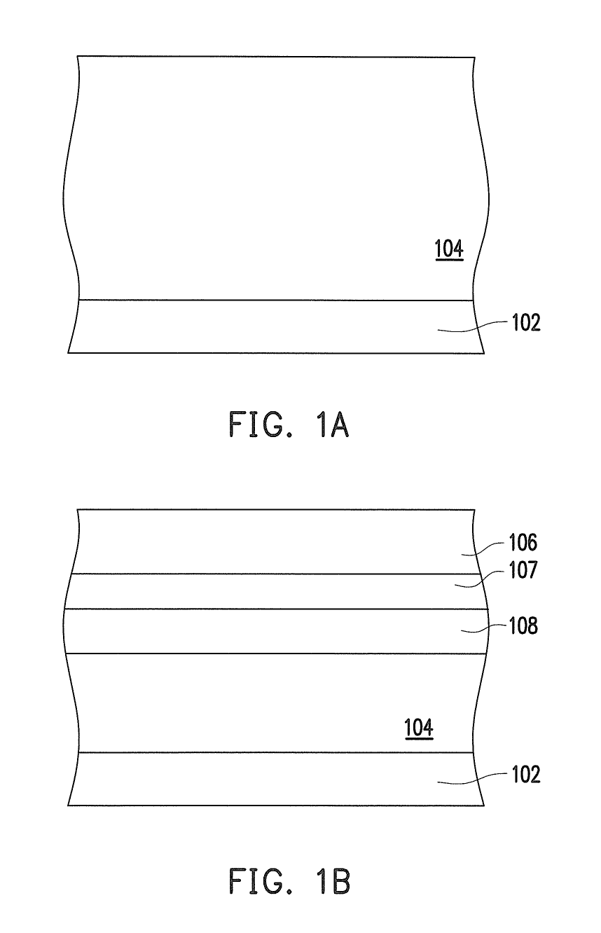

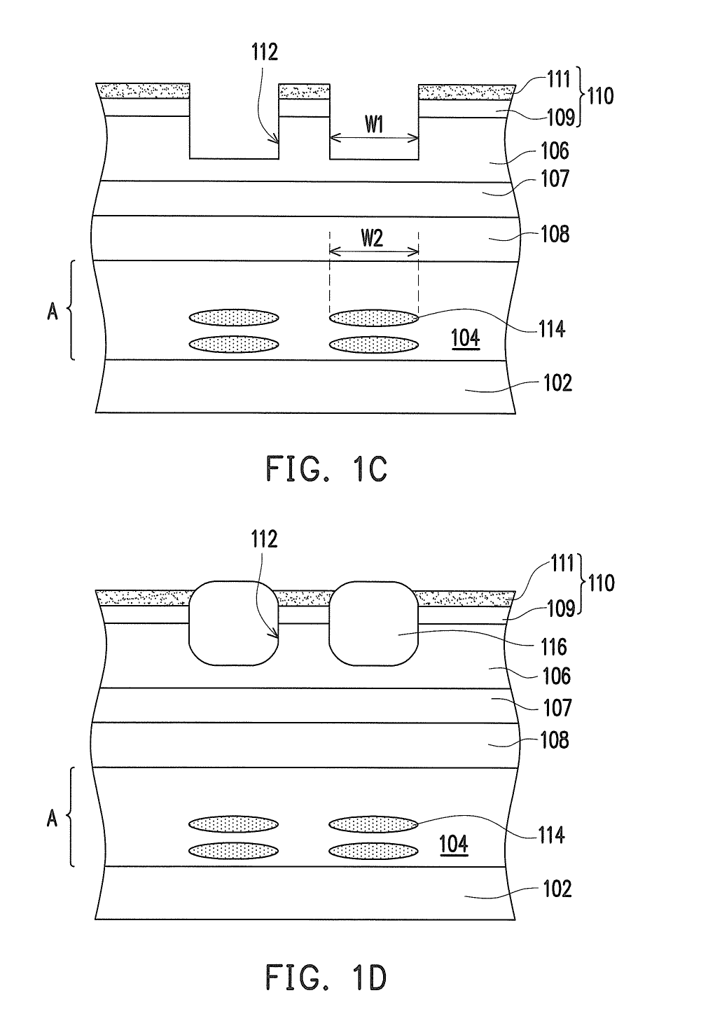

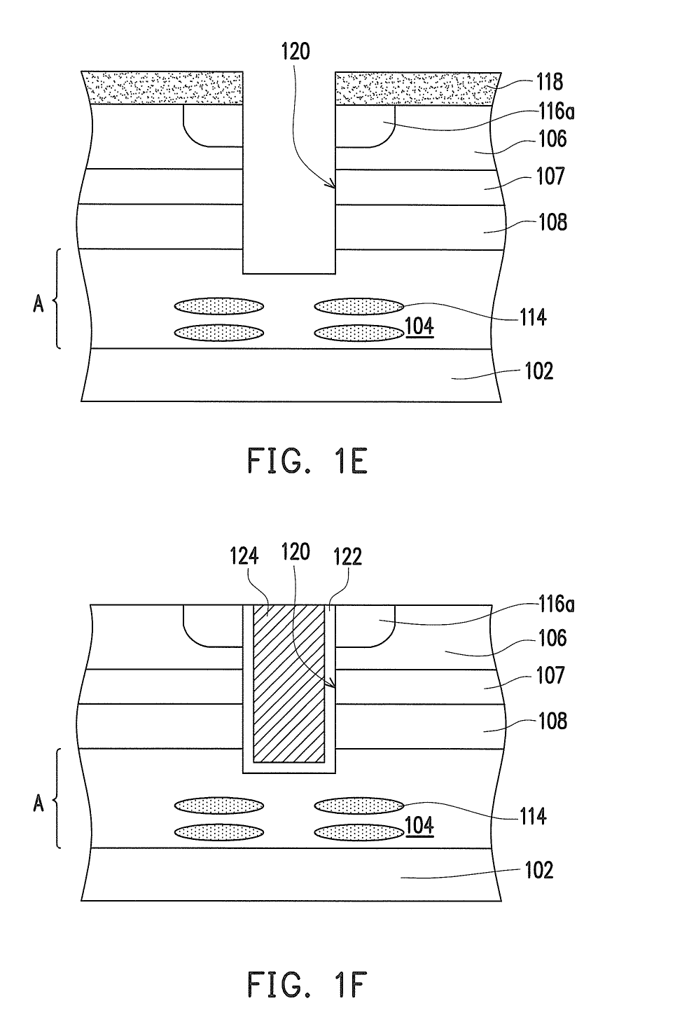

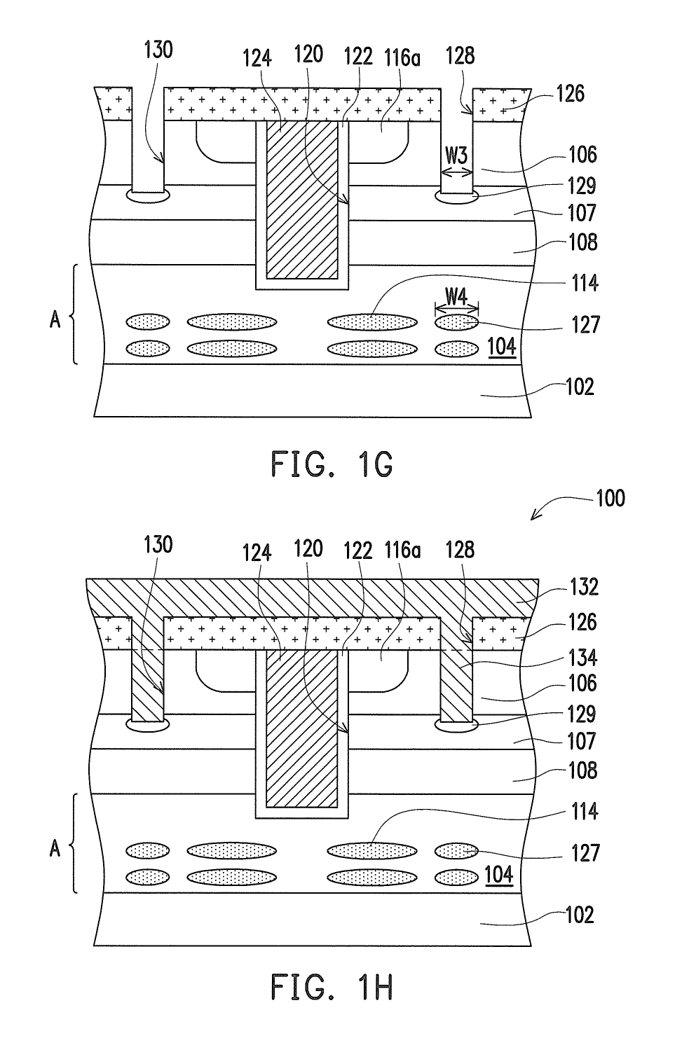

FIGS. 1A to 1H are schematic cross-sectional views of a method of forming a trench gate MOSFET according to an embodiment of the invention.

First, referring to FIG. 1A, an epitaxial layer 104 of a first conductivity type is totaled on a substrate 102 of the first conductivity type. The substrate 102 can be an N-type heavily doped (N⁺) silicon substrate that can be used as a drain of a trench gate MOSFET. The epitaxial layer 104 can be an N-type lightly doped (N⁻) epitaxial layer, and a forming method thereof includes performing a selective epitaxy growth (SEG) process.

Please refer to FIG. 1B, a source region 106 of the first conductivity type, a doped region 107 of a second conductivity type and a doped region 108 of the first conductivity region (from top to bottom counting from the surface of the epitaxial layer 104) are formed in the epitaxial layer 104. The doped region 107 can be a P⁻ doped region that defines a P-type body well. The doped region 108 can be an N-type doped region, and a doping concentration thereof is higher than a doping concentration of the N-type substrate 102. The doped region 108 can provide a lower resistance path to reduce Rds(ON) of the device.

In an embodiment, a first blanket implant process can be performed with an N-type dopant to form a bulk N⁺ doped region (not shown) in the epitaxial layer 104. The N-type dopant includes phosphorous or arsenic. Then, a second blanket implant process is performed with a P-type dopant to form a P⁻ doped region used as the doped region 107 in the bulk N⁺ doped region. The P-type dopant includes boron. Here, the remaining bulk N⁺ doped region above the P⁻ doped region can be used as the source region 106 and the remaining bulk N⁺ doped region below the P⁻ doped region can be used as the doped region 108.

In another embodiment, a method of forming each of the source region 106, the doped region 107, and the doped region 108 includes performing a blanket implant process, and the invention does not limit the order of formation thereof.

It should be mentioned that, the step of forming the doped region 108 is an optional step and can be omitted according to process needs. In other words, two blanket implant processes can be performed to form only the source region 106 and the doped region 107 in the epitaxial layer 104.

Referring to FIG. 1C, a patterned mask layer 110 is formed on the epitaxial layer 104. A material of the patterned mask layer 110 includes silicon oxide, silicon nitride, silicon oxynitride, or a combination thereof and a forming method thereof includes performing a chemical vapor deposition (CVD) process. In an embodiment, the patterned mask layer 110 can include a stack structure of a silicon oxide layer 109 and a silicon nitride layer 111, as illustrated in FIG. 1C. In another embodiment (not shown), the patterned mask layer 110 can be a single material layer. Then, an etching process is performed by using the patterned mask layer 110 as a mask, so as to remove a portion of the epitaxial layer 104, and therefore formed at least two trenches 112 in the source region 106. In an embodiment, the depth of the trenches 112 is less than the depth of the source region 106, as illustrated in FIG. 1C.

Next, at least one doped region 114 of the second conductivity type is formed in the epitaxial region 104 below each of the trenches 112. The doped regions 114 are located below the doped region 108. The doped regions 114 can be P-type doped regions. A method of forming the doped regions 114 includes performing at least one ion implant process. The number and the depth of the at least one doped region 114 can be adjusted according to process needs. Since the ion implant process uses the patterned mask layer 110 as the mask, the process can be regarded as a self-aligned process. Also, a width W2 of each doped region 114 is substantially equal to a width W1 of each trench 112. In an embodiment, two doped regions 114 corresponding to each of the trenches 112 are disposed in the epitaxial layer 104 below the doped region 108. The two doped regions 114 are vertically arranged and separated from each other, as illustrated in FIG. 1C. However, the invention is not limited to those described herein. In another embodiment (not shown), one or more than two doped regions 114 can be disposed in the epitaxial layer 104 below each of the trenches 112.

Referring to FIG. 1D, insulating layers 116 completely fill the trenches 112, respectively. A material of the insulating layers 116 includes silicon oxide. A method of forming the insulating layers 116 includes performing a local oxidation of silicon (LOCOS), a thermal oxidation process, or a chemical vapor deposition (CVD) process. In an embodiment, each insulating layer 116 is a silicon oxide layer formed by the local oxidation of silicon, as shown in FIG. 1D. In another embodiment (not shown), a blanket oxide layer is formed on the epitaxial layer 104 filling in the trenches 112 by performing a high-density plasma (HDP) chemical vapor deposition process.

Referring to FIG. 1E, the patterned mask layer 110 and the insulation layers 116 exceeding the surface of the epitaxial layer 104 are removed. A method of removing the patterned mask layer 110 includes performing an etching process. A method of removing the insulating layer 116 exceeding the surface of the epitaxial layer 104 includes performing a chemical mechanical polishing (CMP) process or an etching back process. Here, the remaining insulating layers 116 in the trenches 112 respectively form the isolation structures 116a.

Next, a patterned mask layer 118 is formed on the epitaxial layer 104. The patterned mask layer 118 at least exposes the epitaxial layer 104 between the isolation structures 116a. In an embodiment, the patterned mask layer 118 exposes the epitaxial layer 104 between the isolation structures 116a and a portion of the isolation structures 116a. A material of the patterned mask layer 118 includes silicon nitride and a forming method thereof includes performing a chemical vapor deposition process. Then, an etching process is performed by using the patterned mask layer 118 as a mask, so as to remove a portion of the epitaxial layer 104 and a portion of the isolation structures 116a, and therefore form a trench 120 in the epitaxial layer 104. Here, the isolation structures 116a are located beside the trench 120 and in contact with the trench 120. In an embodiment, the trench 120 penetrates though the source region 106, the doped region 107 and the doped region 108 and extends to a portion of the epitaxial layer 104 below the doped region 108. Then, the patterned mask layer 118 is removed.

Referring to FIG. 1F, an insulating layer 122 is formed in the trench 120. A material of the insulating layer 122 includes silicon oxide. A method of forming the insulating layer 122 includes performing a thermal oxidation process, or a chemical vapor deposition (CVD) process. Next, a conductive layer 124 completely fills the trench 120. A method of forming the conductive layer 124 includes forming a conductive material layer (not shown) on the epitaxial layer 104 filling in the trench 120. A material of the conductive material layer includes doped poly-silicon and a forming method thereof includes performing a chemical vapor deposition process. Then, a chemical mechanical polishing process or an etching back process is performed to remove the conductive material layer located outside the trench 120.

Referring to FIG. 1G, a dielectric layer 126 is formed on the epitaxial layer 104. The dielectric layer 126 includes silicon oxide, borophosphosilicate glass (BPSG), phosphosilicate glass (PSG), fluorosilicate glass (FSG), or undoped silicon glass (USG), and a forming method thereof includes performing a chemical vapor deposition process. Then, at least one opening 128 is formed in the dielectric layer 126. A method of forming the opening 128 includes performing photolithography and etching processes.

Next, using the dielectric layer 126 as a mask, an etching process is performed to form two trenches 130 in the epitaxial layer 104 beside the trench 120. In an embodiment, the trenches 130 penetrate though the source region 106 and extend to a portion of the doped region 107.

Then, a plurality of doped regions 129 are formed in the doped region 107 below the trenches 130. The doped regions 129 can be P⁺ doped regions. A method of forming the doped regions 129 includes performing an ion implant process and subsequently a driven-in process. Since the ion implant process uses the dielectric layer 126 as the mask, the process can be regarded as a self-aligned process. The doped regions 129 cover the entire bottom and a portion of sidewalls of the trenches 130.

Furthermore, at least one doped region 127 of the second conductivity type is formed in the epitaxial layer 104 below each of the trenches 130. Each doped region 127 is located below the doped region 108. Particularly, it should be mentioned that the doped regions 127 can be formed at any time after or before the step of forming the doped regions 129, or the doped regions 127 can be formed simultaneously with the doped regions 129. The invention does not pose any limitation to time point of forming the doped regions 127.

The doped regions 127 can be P-type doped regions. A method of forming the doped regions 127 includes performing at least one ion implant process. The number and the depth of the at least one doped region 127 can be adjusted according to process needs. Since the ion implant process uses the dielectric layer 126 as the mask, the process can be regarded as a self-aligned process. Also, a width W4 of each doped region 127 is substantially equal to a width W3 of each trench 130. In an embodiment, two doped regions 127 corresponding to each of the trenches 130 are disposed in the epitaxial layer 104 below the doped region 108. The two doped regions 127 are vertically arranged and separated from each other, as illustrated in FIG. 1G. However, the invention is not limited to those described herein. In another embodiment (not shown), one or more than two doped regions 127 can be disposed in the epitaxial layer 104 below each of the trenches 130.

Particularly, it should be mentioned that a doping concentration of the epitaxial layer 104 below the doped region 108 is equal to a sum of doping concentrations of the at least one doped region 114 and the at least one doped region 127. Specifically, in a block A of the epitaxial layer 104, the N-type doping concentration of the N-type epitaxial layer 104 is equal to the P-type doping concentration of the at least one P-type doped region 114 and the at least one P-type doped region 127. Therefore, the block A is electrically neutral so as to reach charge balance. More specifically, in the block A of the epitaxial layer 104, a super junction structure is formed by alternately disposing the P-type dopant and the N-type dopant, so as to make the device capable of having characteristics of high withstand voltage and low impedance.

Further, according to process needs, the step of forming the doped regions 114 or forming the doped regions 127 can be omitted as an option. For example, only the doped regions 114 are formed in the epitaxial layer 104, or only the doped regions 127 are formed in the epitaxial layer 104, as long as the block A of the epitaxial layer 104 can reach a status of charge balance.

Referring to FIG. 1H, a metal layer 132 is formed on the dielectric layer 126. The metal layer 132 is filled in the trenches 130 and electrically connected to the source region 106. A material of the metal layer 132 includes Ti, TiN, W, Al, or a combination thereof, and a forming method thereof includes performing a deposition process or a sputtering process. The metal layer 132 filled in the trenches 130 forms conductive plugs 134. In other words, the metal layer 132 is electrically connected to the source region 106 through the conductive plugs 134. At this point, the fabrication of the trench gate MOSFET 100 is completed, in which the insulating layer 122 is used as a gate insulating layer and the conductive layer 124 is used as a gate.

In the said embodiments, the first conductivity type is N-type and the second conductivity type is P-type. However, the invention is not limited thereto. Those having ordinary skill in the art should know that the first conductivity type can also be P-type and the second conductivity type be N-type.

In the following, the structure of the trench gate MOSFET of the invention is explained though FIG. 1H. As shown in FIG. 1H, the trench gate MOSFET 100 includes an N-type substrate 102, an N-type epitaxial layer 104, an N-type source region 106, an insulating layer 122, a conductive layer 124, two conductive plugs 134, two isolation structures 116a, a dielectric layer 126, and a metal layer 132. The N-type epitaxial layer 104 is disposed on the N-type substrate 102. The N-type epitaxial layer 104 has at least one trench 120 therein. The N-type source region 106 is disposed in the N-type epitaxial layer 104. The insulating layer 122 used as a gate insulating layer is disposed in the trench 120. The conductive layer 124 used as a gate completely fills the trench 120. The two isolation structures 116a are disposed in the N-type source region 106 beside the trench 120 and in contact with the trench 120. The two conductive plugs 134 are disposed in the N-type epitaxial layer 104 beside the trench 120 and penetrate through the N-type source region 106. The dielectric layer 126 is disposed on the N-type epitaxial layer 104. The metal layer 132 is disposed on the dielectric layer 126 and electrically connected to the N-type source region 106.

It should be mentioned that, in the trench gate MOSFET 100 of the invention, by disposing the isolation structures 116a in the epitaxial layer 104 adjoined to the gate (i.e., the conductive layer 124), the gate-to-source capacitance C_{gs} is effectively reduced, thereby reducing the input capacitance Cᵢₛₛ.

Moreover, the trench gate MOSFET 100 of the invention can further includes a P-type doped region 107, an N-type doped region 108 and P-type doped regions 129. The P-type doped region 107 is disposed in the N-type epitaxial layer 104 below the N-type source region 106. The N-type doped region 108 is disposed in the N-type epitaxial layer 104 below the P-type doped region 107. Moreover, the trench 120 penetrates through the N-type source region 106, the P-type doped region 107 and N-type doped region 108 and extends to a portion of the N-type epitaxial layer 104 below the N-type doped region 108. The N-type doped region 108 is adjoined to sidewall of the trench 120, and a doping concentration of the N-type doped region 108 is higher than a doping concentration of the N-type epitaxial layer 104, and therefore a vertical channel resistance of the device can be effectively reduced. Further, the P-type doped regions 129 are disposed below the conductive plugs 134 so as to effectively reduce the ohmic resistance of the conductive plugs 134.

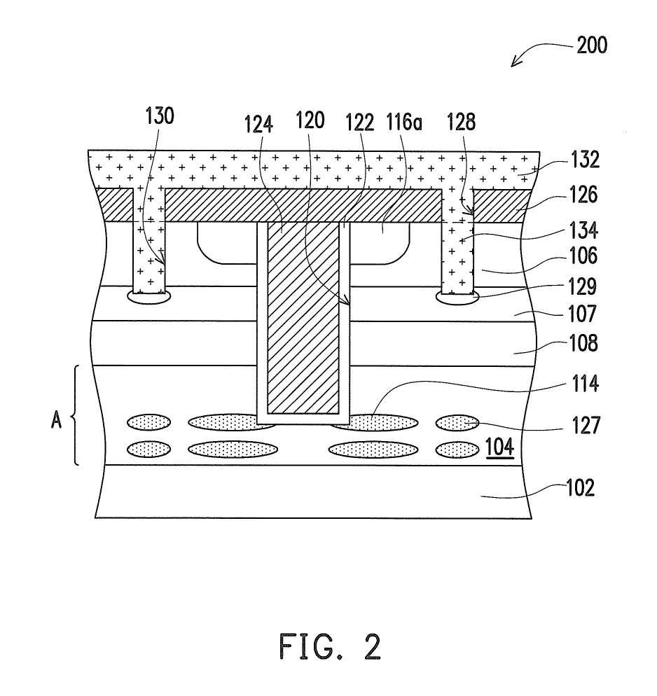

Furthermore, the trench gate MOSFET 100 of the invention can further include at least one P-type doped region 114 and/or at least one P-type doped region 127. The P-type doped regions 114 and 127 are disposed in the N-type epitaxial layer 104 below the N-type doped region 108. In an embodiment, as shown in FIG. 1H, the doped regions 114 correspond to the isolation structures 116a, respectively. A width of the P-type doped regions 104 is substantially equal to or greater than a width of the isolation structures 116a. In an embodiment, the trench 120 and the doped regions 114 are separated from each other, as illustrated in FIG. 1H. In an embodiment, the trench 120 may be in contact with a portion of the doped regions 114. In such manner, a portion of the doped regions 114 are adjoined to bottom corners of the trench 120, and another portion of the doped regions 114 are not in contact with the trench 120, as illustrated in FIG. 2. In another embodiment (not shown), the trench 120 may also be in contact with the entire doped regions 114, so the doped regions 114 are adjoined to the sidewall of the trench 120. Moreover, the P-type doped regions 127 respectively correspond to the conductive plugs 134 and a width thereof is substantially equal to a width of the conductive plugs 134.

Particularly, it should be mentioned that the trench gate MOSFET 100 of the invention, a plurality of the P-type doped regions 114 and 117 are disposed in the N-type epitaxial layer 104 and separated from each other. A supper junction structure is formed by alternatively disposing the N-type dopant and the P-type dopant, as illustrated in the block A of FIG. 1H. The super junction structure has the characteristics of high withstand voltage and low impedance.

In summary, in the trench gate MOSFET of the invention, by disposing the isolation structures in the epitaxial layer adjoined to the gate, the gate-to-source capacitance C_{gs} is effectively reduced, thereby reducing the input capacitance Cᵢₛₛ. Furthermore, the super junction structure is formed in the epitaxial layer so as to make the device capable of having characteristics of high withstand voltage and low impedance. As compared to the conventional MOSFET, in the same unit area, the structure of the invention can achieve lower Ron and switching loss, thereby increasing the power density of each unit area and significantly improving the competitive advantage of the product. Moreover, the method of the invention is relatively simple, and no additional photomask is needed. The super junction structure can be completed by using at least one self-aligned process, thereby significantly lowering cost and improving competitiveness.

Although the invention has been described with reference to the above embodiments, it will be apparent to one of the ordinary skill in the art that modifications and variations to the described embodiments may be made without departing from the spirit and scope of the invention. Accordingly, the scope of the invention will be defined by the attached claims not by the above detailed descriptions.

What is claimed is:

1. A method of forming a trench gate MOSFET, comprising:
forming an epitaxial layer of a first conductivity type on a substrate of the first conductivity type;
forming a source region of the first conductivity type in the epitaxial layer;
faulting at least two first trenches in the source region;
completely filling a plurality of first insulating layers in the first trenches to form a plurality of isolation structures, respectively;
forming a second trench in the epitaxial layer, wherein the isolation structures are located beside the second trench and in contact with the second trench;
forming a second insulating layer in the second trench;
filling a first conductive layer in the second trench;
forming two third trenches in the epitaxial layer beside the second trench; and
filling a plurality of second conductive layers respectively in the third trenches.

2. The method as claimed in claim 1, further comprising, before forming the first trenches:
forming a first doped region of a second conductivity type in the epitaxial layer below the source region; and
forming a second doped region of the first conductivity type in the epitaxial layer below the first doped region.

3. The method as claimed in claim 2, wherein a method of forming each of the source region, the first doped region and the second doped region comprises performing a blanket implant process.

4. The method as claimed in claim 2, wherein a doping concentration of the second doped region is higher than a doping concentration of the epitaxial layer.

5. The method as claimed in claim 2, further comprising, after forming the first trenches and before completely filling the first insulating layers in the first trenches:
forming at least one third doped region in the epitaxial layer below each of the first trenches, wherein the at least one third doped region is located below the second doped region.

6. The method as claimed in claim 5, wherein the third doped region is separated from the second trench.

7. The method as claimed in claim 5, wherein a portion of the third doped region is in contact with the second trench.

8. The method as claimed in claim 5, further comprising, after forming the third trenches in the epitaxial layer beside the second trench and before filling the second conductive layers respectively in the third trenches:
forming at least one fourth doped region of the second conductivity type in the epitaxial layer below each of the third trenches, wherein the at least fourth doped region is located below the second doped region.

9. The method as claimed in claim 8, wherein a doping concentration of the epitaxial layer below the second doped region is equal to a sum of doping concentrations of the at least one third doped region and the at least one fourth doped region.

10. The method as claimed in claim 2, further comprising, after forming the third trenches and before filling the second conductive layers respectively in the third trenches:
forming a third doped region of the second conductive layer in the first doped region below each of the third trenches.

11. The method as claimed in claim 1, wherein a method of forming the first insulating layers comprises a local oxidation of silicon (LOCOS), a thermal oxidation process, or a chemical vapor deposition process.

12. The method as claimed in claim 1, wherein the first conductivity type is N-type and the second conductivity type is P-type, or the first conductivity type is P-type and the second conductivity type is N-type.

13. A trench gate MOSFET, comprising:
a substrate of a first conductivity type;
an epitaxial layer of the first conductivity type, disposed on the substrate, wherein the epitaxial layer has at least one trench;
a source region of the first conductivity type, disposed in the epitaxial layer;
an insulating layer, disposed in the trench;
a conductive layer, completely filling the trench;
two isolation structures, disposed in the source region beside the trench and electrically connected to the trench; and
two conductive plugs, disposed in the epitaxial layer beside the trench and penetrating through the source region.

14. The trench gate MOSFET as claimed in claim 13, further comprising:
a first doped region of a second conductivity type, disposed in the epitaxial layer below the source region; and
a second doped region of the first conductivity type, disposed in the epitaxial layer below the first doped region.

15. The trench gate MOSFET as claimed in claim 14, wherein a doping concentration of the second doped region is higher than a doping concentration of the epitaxial layer.

16. The trench gate MOSFET as claimed in claim 14, further comprising:
at least two third doped regions of the second conductivity type, disposed in the epitaxial layer below the second doped region, wherein the third doped regions correspond to the isolation structures, respectively.

17. The trench gate MOSFET as claimed in claim 16, wherein the third doped regions are separated from the trench.

18. The trench gate MOSFET as claimed in claim 16, wherein a portion of the third doped regions is in contact with the trench.

19. The trench gate MOSFET as claimed in claim 16, wherein a width of each of the third doped regions is substantially equal to or greater than a width of each of the isolation structures.

20. The trench gate MOSFET as claimed in claim 16, further comprising:
at least two fourth doped regions of the second conductivity type, disposed in the epitaxial layer below the second doped region, wherein the fourth doped regions correspond to the conductive plugs, respectively.

21. The trench gate MOSFET as claimed in claim 20, wherein a doping concentration of the epitaxial layer below the second doped region is equal to a sum of doping concentrations of the at least two third doped regions and the at least two fourth doped regions.

22. The trench gate MOSFET as claimed in claim 14, further comprising:
two third doped regions of the second conductivity type, disposed in the first doped region below the conductive plugs.

23. The trench gate MOSFET as claimed in claim 13, wherein a material of the conductive layer comprises doped poly-silicon, a material of the conductive plugs comprises Ti, TiN, W, Al, or a combination thereof, and a material of the isolation structures comprises silicon oxide.

24. The trench gate MOSFET as claimed in claim 13, further comprising:
a dielectric layer, disposed on the epitaxial layer; and
a metal layer, disposed on the dielectric layer and electrically connected to the source region.

25. The trench gate MOSFET as claimed in claim 14, wherein the first conductivity type is N-type and the second conductivity type is P-type, or the first conductivity type is P-type and the second conductivity type is N-type.
